(19) United States
(12) Patent Application Publication
(10) Pub. No.: US 2003/0042601 A1
(43) Pub. Date: Mar. 6, 2003

(54) Electronic module and communication module using the same

(76) Inventors: Mitsuo Ariie, Tokyo-to (JP); Yutaka Ida, Yokohama-shi (JP); Yoshikazu Yagi, Shiga-ken (JP)

Correspondence Address: DICKSTEIN SHAPIRO MORIN & OSHINSKY LLP, Steven I. Weisburd, 41st Floor, 1177 Avenue of the Americas, New York, NY, 10036-2714, US

(21) Appl. No.: 10/230,764

(22) Filed: Aug. 28, 2002

(30) Foreign Application Priority Data
Aug. 30, 2001 (JP) 2001-261395

(51) Int. Cl. H01L 23/48; H01L 29/40; H01L 23/52

(52) U.S. Cl. 257/723; 257/664; 257/690; 257/691; 257/728

(57) ABSTRACT

An electronic module having a semiconductor element and filters provided on a base substrate. The filters have an impedance conversion function and are directly connected to the semiconductor element without the aid of a matching circuit. Since no matching circuit is required between the semiconductor element and the filters, the electronic module can be made smaller and signal transmission loss can be suppressed.

### BACKGROUND OF THE INVENTION

1. Field of the Invention

The present invention relates to an electronic module in which filters and a semiconductor element are embedded and to a communication module using the electronic module.

2. Description of the Related Art

FIG. 9 is a block diagram showing one construction of an amplifier 30 according to the prior art. The amplifier 30 is composed of a semiconductor element 31, which is an active element such as a MES-FET, etc., and matching circuits 32 and 33. In this example, the amplifier 30 is provided in a signal path so as to be inserted between an antenna 34 and a signal processing circuit (not illustrated). The amplifier amplifies a signal output from the signal processing circuit and outputs the signal to the antenna 34. Filters 35 and 36 are provided on both the input and output signal sides of the amplifier 30 thus allowing only a signal in a set frequency band to be input to and output from the amplifier 30.

From the viewpoint of widening the application of such an amplifier and ease of use, it is very common that the input and output impedances of various parts constituting a circuit are designed so as to have a common value (for example, 50 Ω) which is determined in advance.

However, the input and output impedances of the semiconductor element 31 vary from element to element, and the input and output impedances of very few of the semiconductor elements 31 have the common value mentioned above. Therefore, when the general-purpose filters 35 and 36 (that is, filters whose input and output impedances do not have the above-described common value) are directly connected to the semiconductor element 31, there is a problem in that the insertion loss increases due to impedance mismatching.

In order to avoid such a problem, the matching circuits 32 and 33 are provided on the input and output sides of the semiconductor element 31, respectively, and therefore the input and output impedances of the semiconductor element 31 are converted to the above common value by using the matching circuits 32 and 33. As a result, the semiconductor element 31 is impedance matched to the filters 35 and 36.

However, since the matching circuits 32 and 33 are provided on the input and output sides of the semiconductor element 31 in this way, there is a problem in that the amplifier 30 increases in size, and accordingly this prevents reduction in size of a device (for example, communication device) into which the amplifier 30 is put. Furthermore, since signal transmission loss is caused due to the matching circuits 32 and 33, there is a problem that the transmission loss of the signal increases.

### SUMMARY OF THE INVENTION

The present invention was made to solve the above problem, and it is an object of the present invention to provide an electronic module containing a semiconductor element which makes it possible to reduce the size of a device in which the module is to be integrated and reduce the signal transmission loss and to provide a communication module using the electronic module.

In order to attain the above object, in an aspect of the present invention, an electronic module comprises a base substrate, a semiconductor element mounted on the base substrate, and filters mounted on the base substrate. In the electronic module, each filter is a flat filter having an impedance matched to the semiconductor element and each filter is directly connected to the semiconductor element.

In the present invention, the flat filter comprises a resonance circuit and a dielectric substrate on which the resonance circuit is formed and the dielectric substrate is a high permeability substrate whose permeability is higher than that of the semiconductor.

In the present invention, the base substrate comprises a multi-layer substrate and a plurality of dielectric substrates laminated therein and the filter comprises a resonance circuit pattern formed in the multi-layer substrate.

In another aspect of the present invention, an electronic module comprises a base substrate, a semiconductor element mounted on the base substrate, and filters mounted on the base substrate. The electronic module further comprises a filter directly connected to a signal input portion of the semiconductor element and a filter directly connected to a signal output portion of the semiconductor element.

In the present invention, the base substrate comprises a multi-layer substrate and a plurality of dielectric substrates laminated therein and a bias circuit formed inside the multi-layer substrate.

In the present invention, on the base substrate, two transistor elements constituting the semiconductor elements are provided and the filters comprising an input-side filter to be commonly connected to the signal input portion of each of the transistor elements and an output-side filter to be commonly connected to the signal output portion of each of the transistor elements are provided, the input-side filter converts an input AC signal into two AC signals having opposite phase to each other and the same amplitude and applies each of the signals to the transistor elements separately and the output-side filter synthesizes the two AC signals having opposite phase to each other and the same amplitude applied from each of the transistor elements to output a composite signal, and the two transistor elements, the input-side filter, and the output-side filter constitute a push-pull circuit.

In the present invention, the two transistor elements are integrated into a single chip.

In the present invention, a shielding cap for covering the semiconductor element and the filters with a space between the cap and the semiconductor element and filters is provided.

In another aspect of the present invention, a communication module is provided with an electronic module according to the present invention.

In the present invention, the filters have an impedance matched to the semiconductor element. Because of this, the filters can be directly connected to the semiconductor element without impedance mismatching issues. Therefore, a matching circuit is not required between the filters and the semiconductor element. Accordingly, the electronic module can be made smaller, and it becomes possible to reduce the size of a device in which the electronic module is integrated. Furthermore, the signal loss can be reduced since no matching circuit is provided.

### BRIEF DESCRIPTION OF THE DRAWINGS

FIG. 1A is a perspective illustration of an electronic module of a first embodiment of the present invention;

FIG. 1B is a block diagram of the electronic module of the first embodiment;

FIG. 2 is a sectional illustration of the electronic module of the first embodiment;

FIGS. 3A to 3G are perspective illustrations of examples of flat filters in which a resonance circuit is formed on a dielectric substrate;

FIG. 4A shows reflection and transmission characteristics of impedance matched filters;

FIG. 4B shows reflection and transmission characteristics of non-impedance matched filters;

FIG. 5A is a sectional illustration of an electronic module of a second embodiment of the present invention;

FIG. 5B is a circuit diagram of the electronic module of the second embodiment;

FIG. 6A is a perspective illustration of an electronic module of a third embodiment of the present invention;

FIG. 6B is a block diagram of the electronic module of the third embodiment;

FIGS. 7A to 7E are perspective illustrations of examples of filters having a balanced-to-unbalanced conversion function;

FIGS. 8a to 8C are sectional illustrations of electronic modules of other embodiments of the present invention; and

FIG. 9 is a block diagram showing one construction of an amplifier according to the prior art.

### DESCRIPTION OF THE PREFERRED EMBODIMENTS

Hereinafter, the embodiments according to the present invention will be described with reference to the drawings.

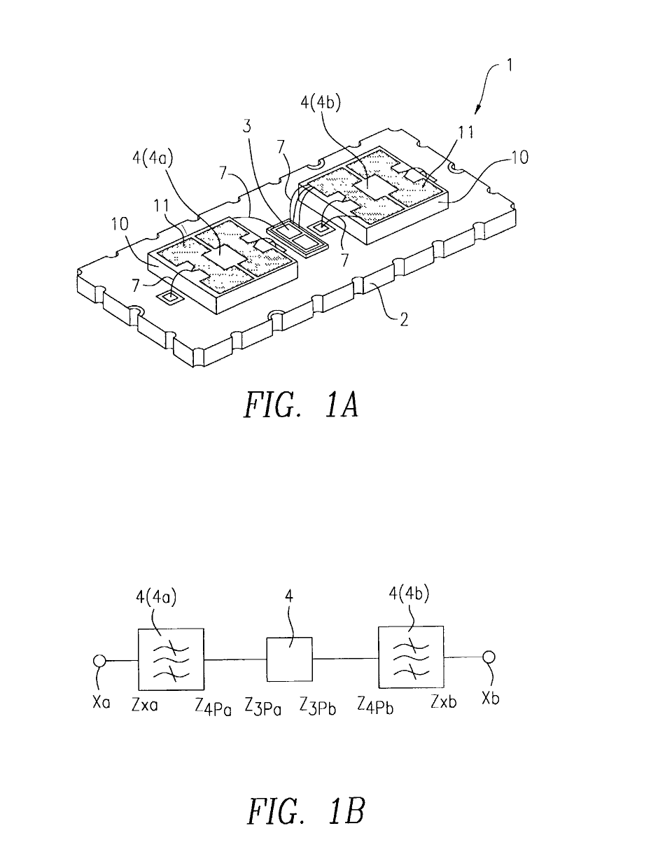

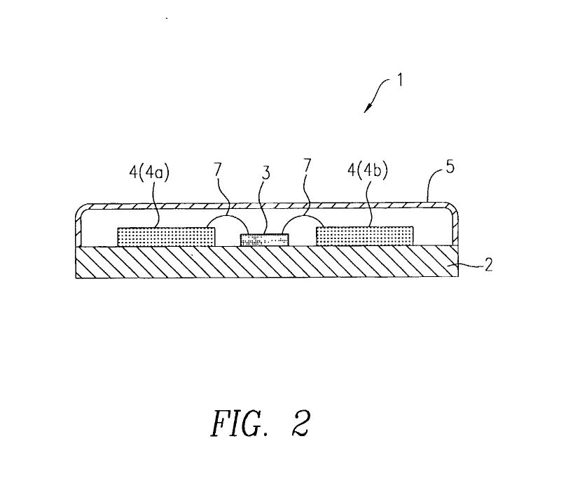

FIG. 1A is a perspective schematic illustration of a main part of an electronic module according to a first embodiment of the present invention, and FIG. 2 is a sectional view of the first embodiment.

An electronic module 1 comprises a base substrate 2, a semiconductor element 3 (for example, an active element such as a MES-FET, etc.), filters 4 (4a and 4b), and a shielding cap 5. That is, in the first embodiment, the semiconductor element 3 is mounted on the base substrate 2 and the filters 4 (4a and 4b) are provided on either side of the semiconductor element 3, with a space therebetween.

In the first embodiment, one of the filters 4a and 4b (the filter is here assumed to be the filter 4a to make the description easier) is directly connected to the input side of the semiconductor element 3 and the other (the filter 4b) is directly connected to the output side of the semiconductor element 3 by bonding wires 7 without using any matching circuit therebetween, as shown in the circuit diagram in FIG. 1B.

In the first embodiment, the shielding cap 5 is disposed so as to cover the semiconductor element 3 and the filters 4a and 4b, a space being provided between the shielding cap 5 and the semiconductor element 3 and filters 4a and 4b. The shielding cap 5 is bonded to the base substrate 2 to shield the space containing the semiconductor element 3 and the filters 4a and 4b. The shielding cap 5, which is preferably made of metal, protects the semiconductor element 3, the filters 4a and 4b, etc., and is connected to a grounding portion of the base substrate 2 to electromagnetically shield the semiconductor element 3, the filters 4a and 4b, etc.

Such an electronic module 1 is surface-mounted on a circuit board of a communication device, for example, by making the bottom surface of the base substrate a mounting surface, and thus the electronic module 1, when put into the circuit of the semiconductor device, forms a communication module and functions, for example, as an amplifier.

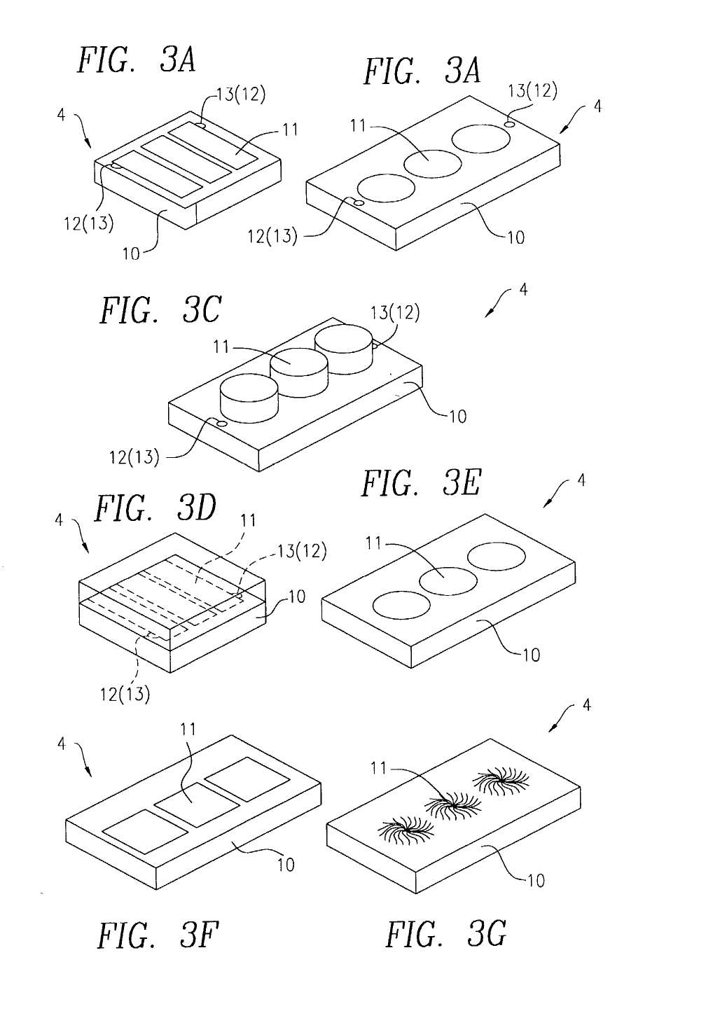

In the first embodiment, the filters 4 (4a and 4b) are constructed as flat filters. Each flat filter is composed of a resonance circuit 11 formed on a dielectric substrate 10 and can be modified in various ways. The construction of various flat filters are shown in FIGS. 3A to 3G. FIG. 3A shows a TEM-mode λ/2 resonance filter, FIG. 3B shows a TM010-mode resonance filter, FIG. 3C shows a TE01δ-mode resonance filter, and FIG. 3D shows a TEM-mode λ/4 resonance filter. Both flat filters in FIGS. 3E and 3F are TM010-mode resonance filters having surfaces which are symmetrical. In the filters in FIGS. 3E and 3F, the patterns in the resonance circuits 11 are different from each other. Furthermore, the flat filter in FIG. 3G is a multi-spiral resonance filter proposed in Japanese Unexamined Patent Application Publication No. 2000-244213, the disclosure of which is incorporated herein by reference. Moreover, in FIGS. 3A to 3G, reference numeral 12 denotes a signal input portion for supplying a signal to the resonance circuit 11 and reference numeral 13 denotes a signal output portion for outputting a signal from the resonance circuit 11.

Therefore, there are flat filters of various constructions and here a flat filter of any construction can be adopted. However, in the first embodiment, in order to make the filter smaller, the dielectric substrate 10 is made of a substrate whose permeability is higher than that of the semiconductor.

In the first embodiment, the semiconductor element 3 is directly connected to the filters 4a and 4b, as described above. The reason why such a construction is possible is that each of the filters 4a and 4b has impedance characteristics particular to the semiconductor element 3.

That is, assuming that Z_{4Pa} is the output impedance of the input-side filter 4a, Z_{3Pa} is the input impedance of the semiconductor element 3, Z_{3Pb} is the output impedance of the semiconductor element 3, and Z_{4Pb} is the input impedance of the output-side filter 4b, in the first embodiment, when the electronic module is a general amplifier, the output impedance Z_{4Pa} (impedance on the semiconductor element 3 side) of the input-side filter 4a and the input impedance Z_{3Pa} of the semiconductor element 3 are designed so as to be substantially equal to each other. Furthermore, the input impedance Z_{4Pb} of the filter 4b (impedance on the semiconductor element 3 side) and the output impedance Z_{3Pb} of the semiconductor element 3 are designed so as to be substantially equal to each other.

Furthermore, when the electronic module is a low-noise amplifier, the output impedance Z_{4Pa} of the filter 4a is designed so as to be an impedance showing the nearly lowest noise, and the input impedance Z_{4Pb} of the filter 4b and the output impedance Z_{3Pb} of the semiconductor element 3 are designed so as to be substantially equal to each other.

Moreover, when the electronic module is a power amplifier, the input impedance Z_{4Pb} of the filter 4b is designed so as to preferably be an impedance that produces the maximum output, an impedance that maximizes the power-supply efficiency, etc.

In this way, in each of the filters 4a and 4b, the impedances Z_{4Pa} and Z_{4Pb} on the side where the semiconductor element 3 is connected are matched to the input impedance Z_{3Pa} (for example, 10 Ω) or the output impedance Z_{3Pb} (for example, 10 Ω) of the semiconductor element 3, and accordingly there are no impedance mismatching issues and the filters 4a and 4b can both be directly connected to the semiconductor element 3.

Furthermore, in the first embodiment, from the point of view of widening the application and improving the ease of use, each of the filters 4a and 4b is designed so that the impedances Z_{Xa} and Z_{Xb} on the side where an external circuit is connected may be a specific value (for example, 50 Ω) which is determined in advance. Moreover, there are various ways for designing the filters such that, in the filters 4a and 4b, the impedances Z_{4Pa} and Z_{4Pb} on the semiconductor element 3 side are matched to the semiconductor element 3 and that the impedance Z_{Xa} and Z_{Xb} are a specific value, and, in this embodiment, any appropriate design method may be adopted in accordance with the form of the filters 4. These design methods are known in the art, therefore, the description thereof is omitted.

According to the first embodiment, since the filters 4a and 4b are constructed so as to have impedances matched to the semiconductor element 3, there are no impedance mismatching issues, and the filters 4a and 4b are directly connected to the semiconductor element 3.

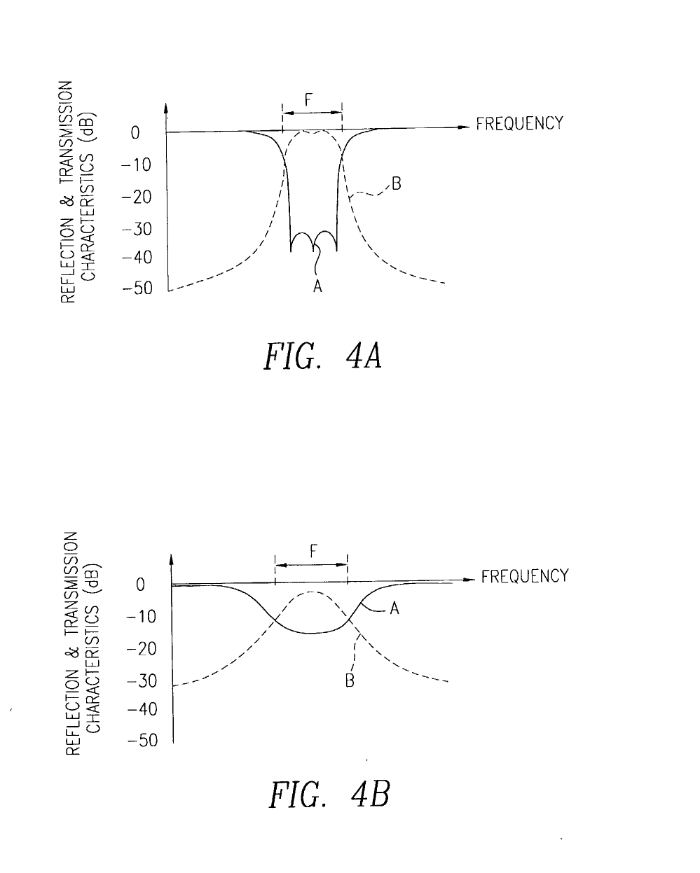

As shown in FIG. 4B, when the filters 4a and 4b have impedances which are not matched to the semiconductor element 3, if the filters 4a and 4b are directly connected to the semiconductor element 3, the filters 4a and 4b have reflection characteristics shown by the solid line A and transmission characteristics shown by the dotted line in FIG. 4B and, because of the impedance mismatching, the insertion loss becomes undesirable in a predetermined transmission frequency band F.

In contrast to this, in the first embodiment of the present invention, since the filters 4a and 4b have impedances matched to the semiconductor element 3, when the filters 4a and 4b are directly connected to the semiconductor element 3, the filters 4a and 4b have the reflection characteristics (solid line A) and transmission characteristics (dotted line B) shown in FIG. 4A and the insertion loss becomes acceptable in a predetermined transmission frequency band F.

Thus, in the first embodiment, with the filters 4a and 4b directly connected to the semiconductor element 3, there is no problem such as the insertion loss increasing due to impedance mismatching, etc., and accordingly no matching circuit is required between the filters 4a and 4b and the semiconductor elements 3. Therefore, since the matching circuit is not required, the electronic module 1 can be made correspondingly smaller. Furthermore, since the matching circuit can be eliminated, the signal transmission loss can be reduced.

Furthermore, in the first embodiment, since the impedances Z_{Xa} and Z_{Xb} on the side where the filters 4a and 4b are connected to the outside is set to be a specific value (for example, 50 Ω), the electronic module 1 can be directly put into the circuit of, for example, a communication device in which the module is to be integrated. Accordingly, in the first embodiment, no matching circuit for matching the electronic module 1 to the circuit into which the electronic module 1 is to be put is required. This fact is combined with the reduction in size of the electronic module 1 in which no matching circuit is required between the semiconductor circuit 3 and the filters 4a and 4b, as described above, and, as a result, the device in which the module is to be integrated can be made smaller.

Furthermore, in the first embodiment, since a flat filter, in which a resonance circuit 11 is formed on a dielectric substrate 10 of a high permeability, is utilized for the filters 4a and 4b, the filters 4a and 4b can be made smaller because of the flat shape and the high permeability of the dielectric substrate 10. Accordingly, the electric module 1 can be further reduced in size.

Hereinafter, a second embodiment of the present invention is described. This second embodiment is similar to the first embodiment except for the internal construction of the base substrate 2. In the description of the second embodiment, the same portions are given the same reference numerals as in the first embodiment and their description is omitted.

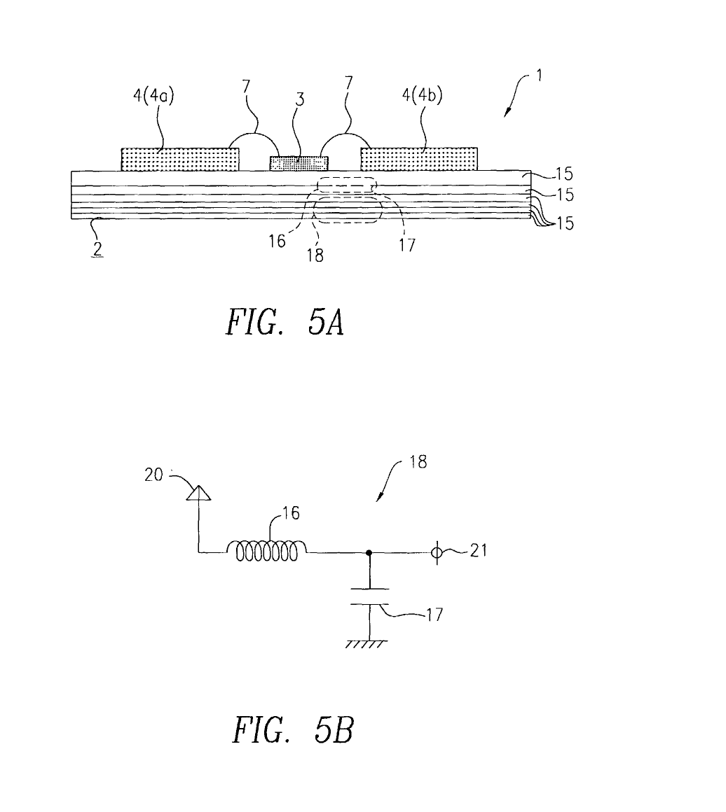

In the second embodiment, as shown in FIG. 5A, the base substrate 2 is a multi-layer substrate in which a plurality of dielectric substrates 15 are laminated. A bias circuit 18 is formed inside the base substrate 2 to apply a bias to the semiconductor element 3. That is, inside the base substrate 2, an inductor 16 and a capacitor 17 are formed and a through-hole and a wiring pattern are formed so as to connect the bias circuit 18 shown in FIG. 5B. Moreover, in FIG. 5B, reference numeral 20 shows a connection portion on the side of the bias circuit 18 to be connected to the semiconductor element 3, and reference numeral 21 shows a connection portion to be connected to a DC power supply.

In the second embodiment, the inductor 16 is preferably composed of a conductor pattern formed on the surface of the substrate 15 inside the base substrate 2. There are various possible patterns for the shape of the conductor pattern functioning as the inductor, such as a spiral pattern, a meandering pattern, etc., but any of them can be adopted in the second embodiment. That is, the conductor pattern is not particularly restricted and can be any conductor pattern desired.

Furthermore, the capacitor 17 is also composed of a conductor pattern formed on the surface of the substrate 15 in the same way as the inductor 16, and a capacitor of an interdigital or a laminated type is preferably formed.

According to the second embodiment, since the bias circuit 18 is formed inside the base substrate 2, there is no need for a separate bias circuit in a device such as a communication device, etc., into which the electronic module 1 is to be put and, accordingly, the device can be made smaller.

Furthermore, the bias circuit 18 is selected to be appropriate for the semiconductor element 3 and, accordingly, since the electronic module 1 is not adversely affected by variations in mounting, variations of parts to be used, etc., as in the case where a bias circuit is provided outside the electronic module, the characteristics of the electronic module 1 are stabilized.

Hereinafter, a third embodiment of the present invention is described. This third embodiment is basically the same as each of the above embodiments except that a push-pull circuit is constructed by using the semiconductor element 3 and the filters 4. In the description of the third embodiment, the same portions are given the same reference numerals as in each of the above embodiments and their description is omitted.

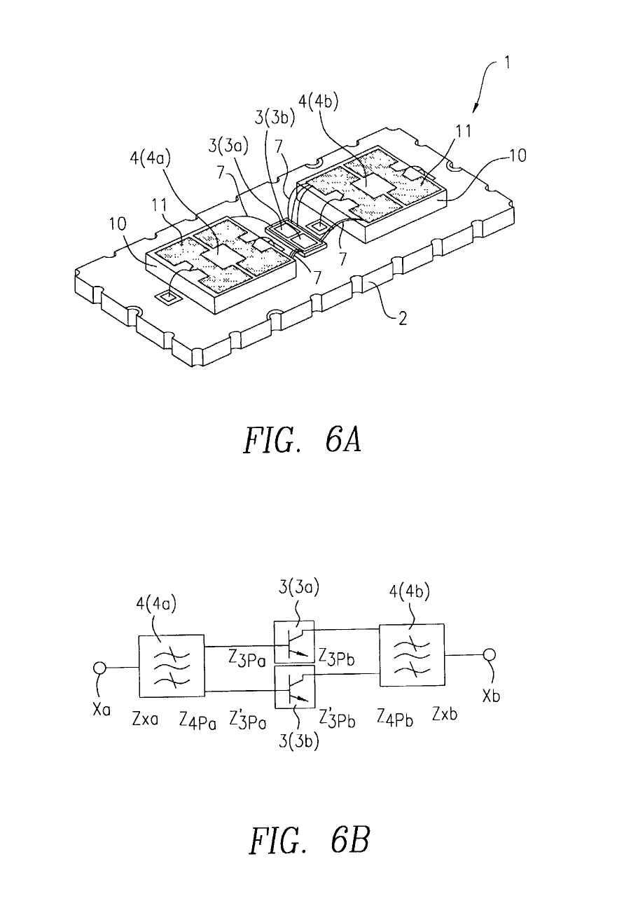

In the third embodiment, as the semiconductor element, transistor elements 3a and 3b are provided on the upper surface of the base substrate 2, as shown in FIG. 6A. These transistor elements 3a and 3b are preferably designed in the same way and integrated to form a pair of transistors as a single chip part.

Furthermore, the filters 4a and 4b are provided on the upper surface of the base substrate 2 on either side of the transistor elements 3a and 3b with a space therebetween.

Also in the third embodiment, the filters 4a and 4b have particular impedance characteristics similar to the above embodiments, and, the signal input portions of the transistor elements 3a and 3b are commonly and directly connected by bonding wires 7 to one of the filters 4a and 4b (here the filter is assumed to be the filter 4a in order to make the description easier), as shown in FIG. 6B. Furthermore, the signal output portions of the transistor elements 3a and 3b are commonly and directly connected by bonding wires 7 to the other filter (filter 4b),.

In the third embodiment, each of the filters 4a and 4b functions as a filter and, at the same time, functions as a balanced-to-unbalanced converter. That is, in the filter 4a, functioning as an input-side filter, an AC signal input from an input portion Xa is converted into two AC signals which are opposite in phase to each other and have the same amplitude and the two signals are input to the transistor elements 3a and 3b, respectively.

In the filter 4b, functioning as an output-side filter, the two AC signals, which are opposite in phase to each other and have the same amplitude, applied by the transistor elements 3a and 3b are combined to output a combined signal from an output potion Xb.

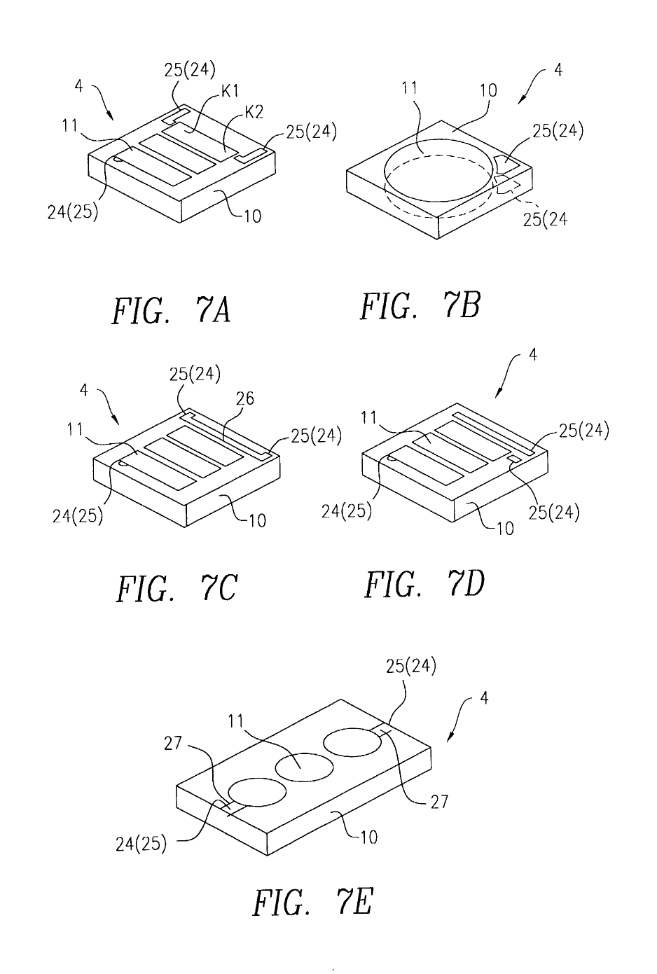

The filters 4a and 4b having such a balanced-to-unbalanced conversion function take a number of forms. FIGS. 7A to 7E each show one possible form of the filters 4a and 4b. Moreover, in FIGS. 7A to 7E, reference numeral 24 denotes an output portion where a signal is output and reference numeral 25 denotes an input portion where a signal is input.

The filter in FIG. 7A is a TEM-mode λ/2 resonator and the filter in FIG. 7B is a TM010-mode resonator. In these filters 4, for example, when two signals having opposite phase to each other are input into both open ends K1 and K2 of a λ/2 resonator by electric field coupling, the resonance circuit 11 is excited based on the signals to output a composite signal of the two signals. In contrast, when the resonance circuit 11 is excited based on an AC signal, two signals having opposite phase to each other and the same amplitude can be output from both open ends K1 and K2 of the λ/2 resonator.

The filter in FIG. 7C is a TEM-mode λ/2 resonator and has an electrode pattern 26 formed so as to be parallel to the pattern of the resonance circuit 11. In the filter of FIG. 7C, two AC signals having opposite phase to each other and the same amplitude are input from both ends of the electrode pattern 26, and a signal is supplied to the resonance circuit 11 from the electrode pattern 26 by magnetic field coupling, thus enabling a composite signal of the two AC signals to be output in the same way as the above. Furthermore, when the signal flows in the opposite direction, one AC signal is converted into two AC signals having the same amplitude and opposite phase to each other to output the signals.

Although the filter in FIG. 7D is a TEM-mode λ/2 resonator, in this example, since one of the two signals having the same amplitude and opposite phase to each other is applied to the resonance circuit 11 by electric field coupling and the other signal is applied to the resonance circuit 11 by magnetic field coupling, the two AC signals are combined to output a composite signal of the two AC signals and the filter is made to have a balanced-to-unbalanced conversion function.

The filter in FIG. 7E is a TM010-mode resonator and, since two signals having the same amplitude and opposite phase to each other are electromagnetically coupled and applied to the resonance circuit 11 through a balanced line 27, the filter can be made to have a balanced-to-unbalanced conversion function.

Thus, the filters having a balanced-to-unbalanced conversion function can take various forms and, in the third embodiment, any desired form may be used.

In the third embodiment, a push-pull circuit is constructed by using the filters 4a and 4b having a balanced-to-unbalanced conversion function and transistor elements 3a and 3b.

According to the third embodiment, when the electronic module is a general amplifier, the output impedance Z_{4Pa} of the filter 4a and the input impedance Z_{3Pa} of the semiconductor element 3 are designed so as to be substantially equal to each other. Furthermore, the input impedance Z_{4Pb} of the filter 4b and the output impedance Z_{3Pb} of the semiconductor element 3 are designed so as to be substantially equal to each other.

Furthermore, when the electronic module is a low-noise amplifier, the output impedance Z_{4Pa} of the filter 4a is designed so as to have an impedance showing nearly the lowest noise, and the input impedance Z_{4Pb} of the filter 4b and the output impedance Z_{3Pb} of the semiconductor element 3 are designed so as to be substantially equal to each other.

Moreover, when the electronic module is a power amplifier, the input impedance Z_{4Pb} of the filter 4b is preferably designed so as to be a desired impedance such as an impedance that produces the maximum output, an impedance that maximizes the power-supply efficiency, etc.

Therefore, without impedance mismatching issues, the transistor elements 3a and 3b can be directly connected to the filters 4a and 4b. In this way, the electronic module 1 can be made so small because no matching circuit is required between the transistor elements 3a and 3b and the filters 4a and 4b, and also a device into which the electronic module 1 is to be put can be made smaller, which is advantageous. Furthermore, the transmission loss of a signal can be made so small because no matching circuit is required.

In this way, the third embodiment has significant advantages in the same way as the above embodiments and, in addition, since the transistor elements 3a and 3b and the filters 4a and 4b constitute a push-pull circuit, the power-supply efficiency can be increased. Moreover, semiconductors to be used in a push-pull circuit are generally operated as a class-B amplifier, but they may be operated as a class-A amplifier or a class-AB amplifier.

Furthermore, in the third embodiment, since a balanced-to-unbalanced conversion function is contained in the filters 4a and 4b themselves, a separate signal distribution circuit for producing a balanced signal to be input to the transistor elements 3a and 3b and a separate synthesizer circuit for synthesizing balanced signals output from the transistor elements 3a and 3b are not required. Accordingly, the size of the electronic module 1 is prevented from increasing, and a push-pull circuit can be constructed. As a result, the electronic module 1 can be made smaller.

Moreover, the present invention is not limited to the above embodiments and various embodiments can be realized. For example, in the above embodiments, although two of the filters 4 are provided in the electronic module 1, the number of the filters 4 can be set in accordance with the application of the electronic module 1, and the number is not limited to two. For example, only the input-side filter may be provided or only the output-side filter may be provided.

Furthermore, in each of the above embodiments, although only one circuit in which the filters 4 and the semiconductor element 3 are connected is provided, a plurality of circuits in which the filters 4 and the semiconductor element 3 are connected may be provided in the electronic module 1. For example, when the electronic module 1 is put into the circuit of a communication device performing transmission and reception in such a way that one circuit including the filters 4 and the semiconductor element 3 is provided between an antenna and a transmission circuit and another circuit including the filters 4 and the semiconductor element 3 is provided between the antenna and a reception circuit, the electronic module 1 can be put into the circuit of a communication device and the electronic module 1 forms a common part for the transmission side and the reception side.

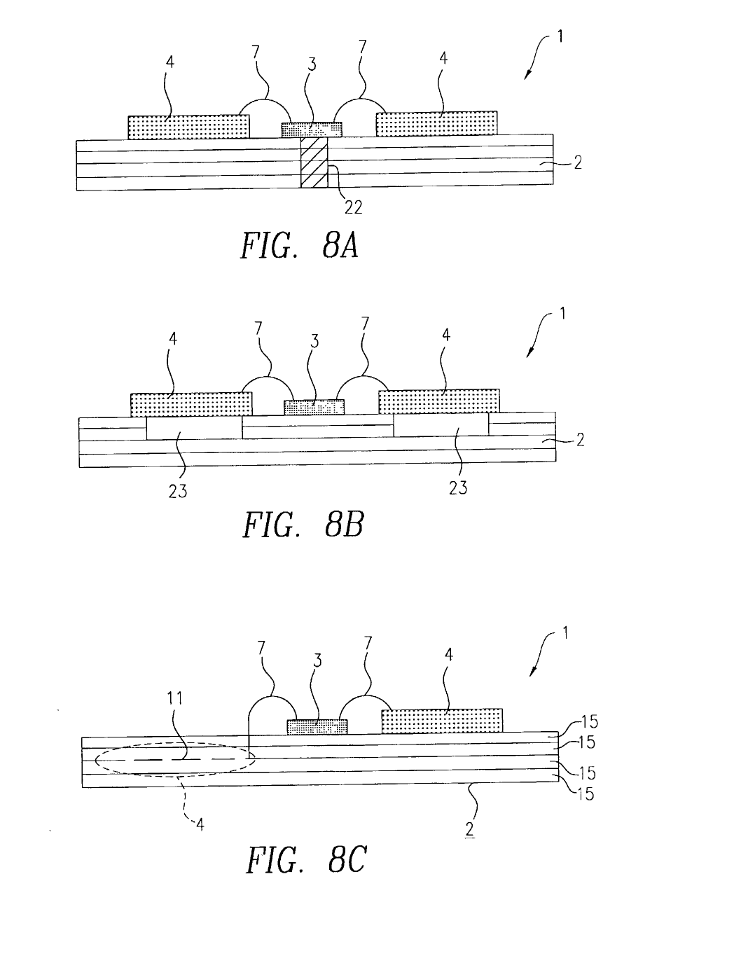

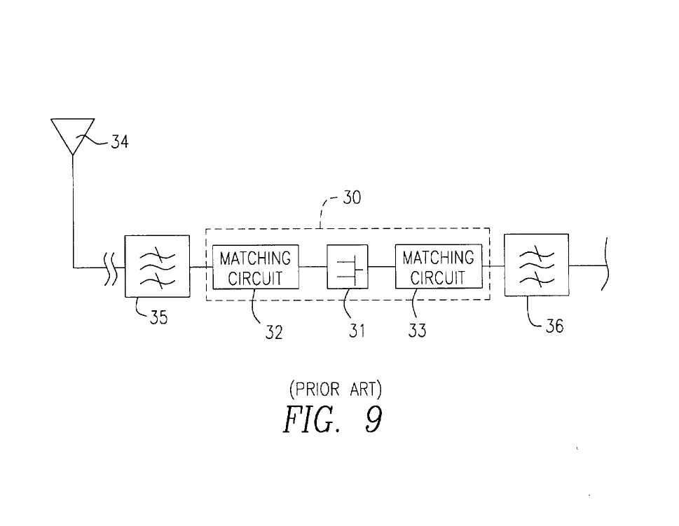

Moreover, when the amount of heat generated by the semiconductor element 3 is high, a thermal veer hole 22 may be provided in the base substrate 2 for dissipating the heat of the semiconductor element 3, as shown in the filter in FIG. 8A.

Moreover, in some filters 4 it is desirable to form a space on both top and bottom surfaces and, when such filters 4 are used, concave portions 23 are formed in the areas in which the filters are formed on the base substrate 2 as shown in the filter in FIG. 8B. Accordingly, the filters may be constructed so as to have a space on both the top and bottom surfaces of the filter.

Moreover, in each of the above embodiments, although the filter 4 is formed such that a resonance circuit 1 is formed on the dielectric substrate 10, when the base substrate 2 is made of a multi-layer substrate, one or both of the filters 4a and 4b may be formed as a flat filter where the pattern of the resonance circuit 11 is formed inside the base substrate 2 itself as shown in FIG. 8C. In this way, when a flat filter 4 is formed inside the base substrate 2 itself, for example, the two flat filters 4a and 4b can be disposed in the vertical direction instead of arranging the flat filters 4a and 4b in parallel in the horizontal direction and, as a result, the electronic module 1 can be further reduced in size.

According to the present invention, a semiconductor element and filters are mounted on a common base substrate to constitute an electronic module and the filters have an impedance matched to the semiconductor element. Accordingly, without impedance mismatching issues, the filters can be directly connected to the semiconductor element without the aid of a matching circuit.

In this way, since no matching circuit is required, the electronic module can be made that much smaller. Furthermore, as the electronic module is reduced in size, a device (for example, a communication module) into which the electronic module is to be put can be also made smaller. Moreover, the signal transmission loss can be reduced accordingly, since no matching circuit is provided.

Moreover, when the filters are made of a flat filter in which a resonance circuit is formed on a dielectric substrate and the dielectric substrate is made of a high permeability substrate having a higher permeability than that of the semiconductor, the filters can be easily made smaller due to the high permeability of the dielectric substrate. Because of the reduction in size of the filters, the electronic module can be made much smaller.

Furthermore, when the base substrate is made of a multi-layer substrate and the filters are constructed such that the pattern of a resonance circuit is formed in the multi-layer substrate itself, since the filters are embedded in the base substrate, the electronic module can be made correspondingly thinner compared with the filter parts mounted on the surface of the base substrate.

When the base substrate is made of a multi-layer substrate and a bias circuit applying a bias to the semiconductor is embedded in the base substrate, the functions of the electronic module can be increased and also the characteristics of the semiconductor element can be improved. Furthermore, since no bias circuit for the semiconductor element of the electronic module is required in a circuit into which the electronic module is put, a device in which the electronic module is integrated can be made smaller.

In an electronic module in which a push-pull circuit is constructed by two transistor elements (serving as the semiconductor element) and filters, the efficiency of an amplifier made of the push-pull circuit can be increased. In addition, when the filters have a balanced-to-unbalanced conversion function, a distribution circuit of a signal for producing a balanced signal to be applied to each of the transistor elements and a synthesizer circuit for synthesizing the balanced signals output from each of the transistor elements become unnecessary, and accordingly, the electronic module can be made smaller. Furthermore, since there is no signal transmission loss due to that distribution circuit and synthesizer circuit, the signal transmission loss can be suppressed.

In an electronic module in which a shielding cap is provided, since the semiconductor element and the filters are protected and shielded by the shielding cap, the reliability of the electronic module can be improved.

Although the present invention has been described in relation to particular embodiments thereof, many other variations and modifications and other uses will become apparent to those skilled in the art. It is preferred, therefore, that the present invention be limited not by the specific disclosure herein, but only by the appended claims.

What is claimed is:

1. An electronic module comprising:
a base substrate;
a semiconductor element mounted on the base substrate; and
at least two filters mounted on the base substrate, wherein each of the at least two filters is a flat filter having an impedance matched to the semiconductor element and wherein each of the at least two filters is directly connected to the semiconductor element.

2. The electronic module as claimed in claim 1, wherein the flat filter is one of a TEM-mode λ/2 resonance filter, a TM010-mode resonance filter, a TE01δ-mode resonance filter, a TEM-mode λ/4 resonance filter and a multi-spiral resonance filter.

3. The electronic module as claimed in claim 1, wherein the flat filter comprises:
a dielectric substrate; and
a resonance circuit formed on the dielectric substrate, the dielectric substrate having a permeability greater than that of the semiconductor element.

4. The electronic module as claimed in claim 1, wherein the base substrate comprises a multi-layer substrate formed from a plurality of dielectric substrates laminated together.

5. The electronic module as claimed in claim 4, wherein at least one of the at least two filters comprises a resonance circuit formed in the multi-layer substrate.

6. The electronic module as claimed in claim 4, wherein a bias circuit is formed inside the multi-layer substrate.

7. The electronic module as claimed in claim 1, wherein:
the semiconductor element includes two transistor elements,
a first of the at least two filters forms an input-side filter connected to a signal input portion of each of the two transistor elements,
a second of the at least two filters forms an output-side filter connected to a signal output portion of each of the two transistor elements,
the input-side filter converts an input AC signal into two AC signals having an opposite phase to each other and the same amplitude and applies each of the two AC signals to a separate one of the two transistor elements, and
the output-side filter synthesizes the two AC signals received from each of the two transistor elements and outputs a composite signal.

8. The electronic module as claimed in claim 7, wherein the two transistor elements, the input-side filter and the output-side filter form a push-pull circuit.

9. The electronic module as claimed in claim 7, wherein the two transistor elements are integrated into a single chip.

10. The electronic module as claimed in claim 1, further comprising a shielding cap that covers the semiconductor element and the at least two filters such that a space is formed between the cap and the semiconductor element and the at least two filters.

11. An electronic module comprising:
a base substrate;
a semiconductor element mounted on the base substrate, the semiconductor element having a signal input portion and a signal output portion;
a first filter mounted on the base substrate and directly connected to the signal input portion of the semiconductor element; and
a second filter mounted on the base substrate and directly connected to the signal output portion of the semiconductor element.

12. The electronic module as claimed in claim 11, wherein at least one of the first and second filters is a flat filter.

13. The electronic module as claimed in claim 12, wherein the flat filter is one of a TEM-mode λ/2 resonance filter, a TM010-mode resonance filter, a TE01δ-mode resonance filter, a TEM-mode λ/4 resonance filter and a multi-spiral resonance filter.

14. The electronic module as claimed in claim 12, wherein the flat filter comprises:
a dielectric substrate; and
a resonance circuit formed on the dielectric substrate, the dielectric substrate having a permeability greater than that of the semiconductor element.

15. The electronic module as claimed in claim 11, wherein the base substrate comprises a multi-layer substrate formed from a plurality of dielectric substrates laminated together.

16. The electronic module as claimed in claim 15, wherein at least one of the first and second filters comprises a resonance circuit formed in the multi-layer substrate.

17. The electronic module as claimed in claim 15, wherein a bias circuit is formed inside the multi-layer substrate.

18. The electronic module as claimed in claim 11, wherein the semiconductor element includes a first transistor element and a second transistor element, the first filter converts an input AC signal into two AC signals and applies one of the two AC signals to the first transistor element and the other of the two AC signals to the second transistor element, the two AC signals having an opposite phase to each other and the same amplitude, and the second filter receives the one AC signal from the first transistor element and the other AC signal from the second transistor element, synthesizes the two AC signals and outputs a composite signal.

19. The electronic module as claimed in claim 18, wherein the first transistor element and the second transistor element are integrated into a single chip.

20. The electronic module as claimed in claim 11, further comprising a shielding cap that covers the semiconductor element, the first filter and the second filter.
